(19) United States
(12) Patent Application Publication
(10) Pub. No.: US 2025/0329659 A1
(43) Pub. Date: Oct. 23, 2025

(54) SEMICONDUCTOR DEVICE

(71) Applicant: Mitsubishi Electric Corporation, Tokyo (JP)

(72) Inventors: Yuji IMOTO, Tokyo (JP); Naohiro OGUSHI, Tokyo (JP); Seiichiro INOKUCHI, Tokyo (JP)

(73) Assignee: Mitsubishi Electric Corporation, Tokyo (JP)

(21) Appl. No.: 18/872,205

(22) PCT Filed: Sep. 9, 2022
(86) PCT No.: PCT/JP2022/033850

§ 371 Date: Dec. 5, 2024

(51) Int. Cl. H01L 23/538; H01L 23/00; H01L 23/31

(52) U.S. Cl. CPC H01L 23/5386; H01L 23/3121; H01L 23/562

(57) ABSTRACT

An object of the present disclosure is to provide a technique capable of more reliably preventing peeling of a sealing member. A semiconductor device includes an insulating substrate, a first conductor layer bonded onto the insulating substrate, a second conductor layer, a sealing member, and a semiconductor element. The second conductive layer is bonded onto the first conductor layer and has an overhang portion that is a side end portion protruding in a side direction from a side end portion of the first conductor layer. The sealing member has a portion buried in a space between the overhang portion and the insulating substrate. The semiconductor element is covered with the sealing member.

### TECHNICAL FIELD

The present disclosure relates to a semiconductor device.

### BACKGROUND ART

A semiconductor device has been proposed in which a slight undercut shape is provided on a side surface of a circuit pattern which is a single conductor layer by etching or pressing (for example, Patent Document 1). According to such a configuration, it is possible to prevent peeling of a sealing member due to temperature change, or the like, by an anchor effect by the undercut shape.

### PRIOR ART DOCUMENT

### Patent Document

Patent Document 1: Japanese Patent No. 6210818

### SUMMARY

### Problem to be Solved by the Invention

In the configuration of the prior art in which the undercut shape is provided on the side surface of the single conductor layer by etching or pressing, the undercut shape depends on a thickness of the conductor layer. Thus, there is a problem that the undercut shape is unstable and an effect of preventing peeling of the sealing member may not be obtained.

Thus, the present disclosure has been made in view of the above problem, and an object thereof is to provide a technique capable of more reliably preventing peeling of a sealing member.

### Means to Solve the Problem

A semiconductor device according to the present disclosure includes an insulating substrate, a first conductor layer bonded onto the insulating substrate, a second conductor layer bonded onto the first conductor layer and having an overhang portion that is a side end portion protruding in a side direction from a side end portion of the first conductor layer, a sealing member having a portion buried in a space between the overhang portion and the insulating substrate, and a semiconductor element covered with the sealing member.

### Effects of the Invention

According to the present disclosure, a second conductor layer has an overhang portion which is a side end portion protruding in a side direction from a side end portion of a first conductor layer, and a sealing member has a portion buried in a space between the overhang portion and the insulating substrate. According to such a configuration, it is possible to more reliably prevent peeling of the sealing member.

Objects, features, aspects, and advantages of the present disclosure will become more apparent from the following detailed description and the accompanying drawings.

### BRIEF DESCRIPTION OF DRAWINGS

FIG. 1 is a cross-sectional view illustrating a configuration of a semiconductor device according to a first embodiment.

FIG. 2 is a cross-sectional view illustrating a configuration of a semiconductor device according to a second embodiment.

FIG. 3 is a cross-sectional view illustrating a configuration of a semiconductor device according to a third embodiment.

FIG. 4 is a cross-sectional view illustrating a configuration of a semiconductor device according to a fourth embodiment.

FIG. 5 is a cross-sectional view illustrating a configuration of a semiconductor device according to a fifth embodiment.

FIG. 6 is a cross-sectional view illustrating a configuration of a semiconductor device according to a sixth embodiment.

FIG. 7 is a cross-sectional view illustrating a configuration of a semiconductor device according to a seventh embodiment.

FIG. 8 is a top view illustrating a configuration of the semiconductor device according to the seventh embodiment.

FIG. 9 is a cross-sectional view illustrating a configuration of a semiconductor device according to an eighth embodiment.

FIG. 10 is a cross-sectional view illustrating a configuration of a semiconductor device according to a ninth embodiment.

FIG. 11 is a top view illustrating a configuration of the semiconductor device according to the ninth embodiment.

FIG. 12 is a cross-sectional view illustrating a configuration of a semiconductor device according to a tenth embodiment.

### DESCRIPTION OF EMBODIMENTS

Hereinafter, embodiments will be described with reference to the accompanying drawings. Features described in the following embodiments are examples, and all features are not necessarily essential. Further, in the following description, similar components in a plurality of embodiments are denoted by the same or similar reference numerals, and different components will be mainly described. Furthermore, in the following description, specific positions and directions such as “upper”, “lower”, “left”, “right”, “front”, or “back” do not have to necessarily coincide with actual positions and directions in practice.

### First Embodiment

FIG. 1 is a cross-sectional view illustrating a configuration of a semiconductor device 100 according to the first embodiment. The semiconductor device 100 includes a ceramic insulating substrate 1, a first conductor layer 2, a second conductor layer 3, a semiconductor element 5, a solder 6, a wire 7, a third conductor layer 8, a base portion 9, and a sealing member 10.

The ceramic insulating substrate 1 is an insulating substrate made of, for example, aluminum nitride (AlN) or silicon nitride (SiN). The first conductor layer 2 is bonded onto the ceramic insulating substrate 1, that is, onto a front surface of the ceramic insulating substrate 1, and the third conductor layer 8 is bonded under the ceramic insulating substrate 1, that is, onto a back surface of the ceramic insulating substrate 1.

The first conductor layer 2 and the third conductor layer 8 have a plurality of circuit patterns. After the first conductor layer 2 is bonded onto the ceramic insulating substrate 1, a circuit pattern may be formed on the first conductor layer 2 by etching, or the like, or after the circuit pattern is formed on the first conductor layer 2 by pressing, or the like, the first conductor layer 2 may be bonded onto the ceramic insulating substrate 1. The circuit pattern of the third conductor layer 8 is formed in a similar manner to the circuit pattern of the first conductor layer 2.

The second conductor layer 3 is bonded onto the first conductor layer 2, that is, onto a front surface of the first conductor layer 2. The second conductor layer 3 has an overhang portion 3a which is a side end portion protruding in a side direction (a direction corresponding to a left-right direction in FIG. 1) with respect to a side end portion of the first conductor layer 2. The overhang portion 3a protrudes in a side direction from the side end portion of the first conductor layer 2 by, for example, about 50 μm. An undercut shape is formed by the side portion of the first conductor layer 2 and the overhang portion 3a of the second conductor layer 3. Note that the second conductor layer 3 may be appropriately patterned so as to maintain a wiring relationship by the circuit pattern of the first conductor layer 2.

A material of the first conductor layer 2 and the second conductor layer 3 is, for example, aluminum or copper including an alloy. For example, in a case where the material of the first conductor layer 2 is aluminum and the material of the second conductor layer 3 is copper, improvement in heat dissipation of the semiconductor device 100 can be expected, or improvement in reliability of the semiconductor device 100 by improvement in rigidity can be expected. A material of the third conductor layer 8 may be the same as the material of the first conductor layer 2. To bond the first conductor layer 2 and the second conductor layer 3, for example, brazing, soldering, welding, liquid phase or solid phase diffusion bonding, or the like, may be used.

The semiconductor element 5 is electrically connected to the second conductor layer 3. In the example of FIG. 1, the semiconductor element 5 is bonded onto a front surface of the second conductor layer 3 by the solder 6. The semiconductor element 5 is, for example, a metal oxide semiconductor field effect transistor (MOSFET), an insulated gate bipolar transistor (IGBT), a reverse conducting-IGBT (RC-IGBT), a Schottky barrier diode (SBD), or a PN junction diode (PND). A material of the semiconductor element 5 may be normal silicon (Si), or a wide band gap semiconductor such as silicon carbide (SiC), gallium nitride (GaN), or diamond. In a case where the material of the semiconductor element 5 is a wide band gap semiconductor, stable operation under high temperature and high voltage, and high switching speed can be achieved.

The semiconductor element 5 is electrically connected to another circuit pattern (not illustrated), or the like, by the wire 7. The material of the wire 7 is, for example, aluminum. The semiconductor element 5 may be electrically connected to another circuit pattern, or the like, by a bus bar (not illustrated) instead of the wire 7. Although not illustrated, another circuit pattern may be electrically connected to an external terminal by, for example, solder or welding.

The base portion 9 is bonded under the third conductor layer 8. The base portion 9 is made of, for example, aluminum, copper, or the like, and is a cooling member such as a pin fin, or a base plate.

The sealing member 10 covers the semiconductor element 5. In the example of FIG. 1, the sealing member 10 also covers the first conductor layer 2, the second conductor layer 3, and the like. A material of the sealing member 10 is, for example, a resin such as epoxy or gel, and the sealing member 10 is formed by transfer molding. Note that the sealing member 10 also fills a portion below the overhang portion 3a. In other words, the sealing member 10 has a portion buried in a space 4 between the overhang portion 3a and the ceramic insulating substrate 1.

### Summary of First Embodiment

In general, a temperature of the semiconductor device changes depending on energization operation or an external environment. If the sealing member 10 is peeled off from the ceramic insulating substrate 1, the first conductor layer 2, the second conductor layer 3, the semiconductor element 5, and the like, due to this temperature change, there is a possibility that reliability of the semiconductor device degrades.

In contrast, according to the semiconductor device 100 of the first embodiment, the second conductor layer 3 has the overhang portion 3a which is a side end portion protruding in the side direction from the side end portion of the first conductor layer 2, and the sealing member 10 has a portion buried in the space 4 between the overhang portion 3a and the ceramic insulating substrate 1. According to such a configuration, it is possible to prevent peeling of the sealing member 10 in a vertical direction by an anchor effect by the overhang portion 3a.

In addition, by making a size of the second conductor layer 3 in the side direction slightly larger than a size of the first conductor layer 2 in the side direction, a length of protrusion of the overhang portion 3a can be stabilized. Thus, the undercut shape can be stabilized regardless of the thickness of the first conductor layer 2, or the like, so that the effect of preventing peeling of the sealing member can be more reliably obtained. In addition, in the configuration in which a plurality of sets of the first conductor layer 2 and the second conductor layer 3 are provided, it is possible to secure insulation between the sets only by securing a distance between the second conductor layers 3, so that, it is easy to secure the insulation.

Note that while in the above description, the length of protrusion of the overhang portion 3a from the side end portion of the first conductor layer 2 has been described as about 50 μm, the length may be 50 μm or more if the size in the side direction of the semiconductor device 100 may be somewhat large.

### Second Embodiment

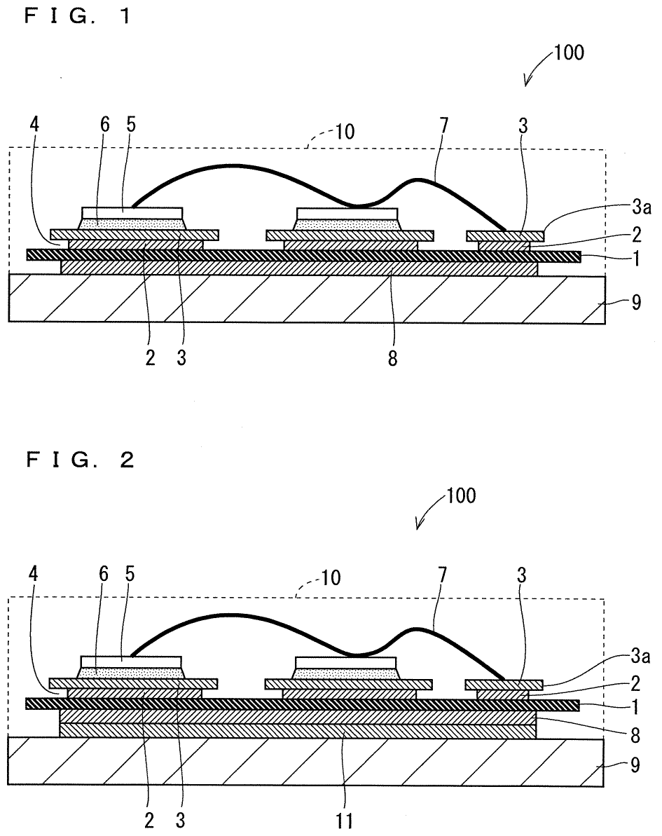

FIG. 2 is a cross-sectional view illustrating a configuration of the semiconductor device 100 according to a second embodiment. The configuration of FIG. 2 is similar to the configuration in which a fourth conductor layer 11 is added in the configuration of FIG. 1. The fourth conductor layer 11 is bonded under the third conductor layer 8 in a similar manner to the second conductor layer 3 being bonded onto the first conductor layer 2. Further, rigidity of the fourth conductor layer 11 is different from rigidity of the third conductor layer 8.

In general, in the ceramic insulating substrate 1 onto which circuit patterns such as the first conductor layer 2 and the third conductor layer 8 are bonded, warpage occurs in the ceramic insulating substrate 1 due to a difference in rigidity between the first conductor layer 2 and the third conductor layer 8. In particular, in a case where the material of the first conductor layer 2 is pure aluminum and the material of the second conductor layer 3 is a copper alloy, for example, relatively large warpage occurs in the ceramic insulating substrate 1.

In contrast, according to the semiconductor device 100 of the second embodiment, the fourth conductor layer 11 having different rigidity from the third conductor layer 8 is bonded under the third conductor layer 8. According to such a configuration, the rigidity of the third conductor layer 8 and the fourth conductor layer 11 can enhance balance of upper and lower rigidity of the ceramic insulating substrate 1, so that warpage of the ceramic insulating substrate 1 can be prevented. By this means, improvement in reliability and assembly easiness of the semiconductor device 100 can be expected.

### Third Embodiment

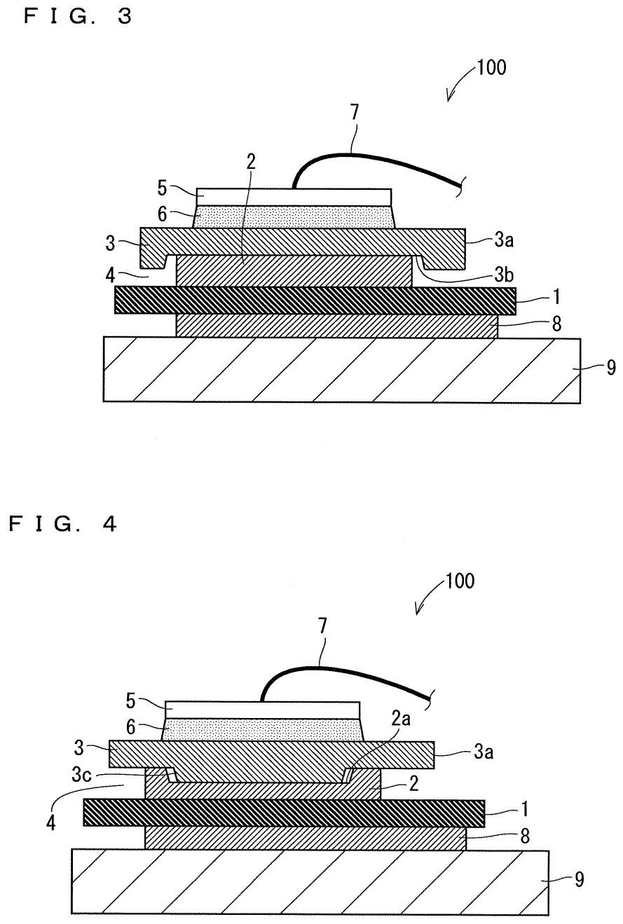

FIG. 3 is a cross-sectional view illustrating a configuration of the semiconductor device 100 according to a third embodiment. Note that illustration of the sealing member 10 is omitted in FIG. 3 and subsequent drawings.

The configuration of FIG. 3 is similar to the configuration in which a recess 3b is provided in the second conductor layer 3 in the configuration of FIG. 1. The recess 3b of the second conductor layer 3 is slightly larger than an upper portion which is part of the first conductor layer 2 and is fitted to the upper portion of the first conductor layer 2. In this state, the second conductor layer 3 is bonded onto the first conductor layer 2. The recess 3b is formed in the second conductor layer 3 by, for example, pressing or machining.

According to the semiconductor device 100 according to the third embodiment as described above, the recess 3b fitted to part of the first conductor layer 2 is provided in the second conductor layer 3. According to such a configuration, at the time of bonding the first conductor layer 2 and the second conductor layer 3, the first conductor layer 2 and the second conductor layer 3 are easily positioned, and misalignment therebetween can be reduced, so that a length of protrusion of the overhang portion 3a can be stabilized. In addition, in the configuration in which a plurality of sets of the first conductor layer 2 and the second conductor layer 3 are provided, a distance between the second conductor layers 3, that is, a distance between the respective sets can be stabilized, so that insulation can be stabilized. In addition, it is possible to prevent decrease in rigidity of the first conductor layer 2.

A shape of the recess 3b in plan view may be a polygon such as a rectangle or a hexagon, or may be a circle. In a case where the shape of the recess 3b in plan view is a polygon, it is possible to prevent rotation of one of the first conductor layer 2 and the second conductor layer 3 with respect to the other.

### Fourth Embodiment

FIG. 4 is a cross-sectional view illustrating a configuration of the semiconductor device 100 according to a fourth embodiment. The configuration of FIG. 4 is similar to the configuration in which a protrusion 3c is provided in the second conductor layer 3 and a recess 2a is provided in the first conductor layer 2 in the configuration of FIG. 1. The protrusion 3c is provided in a central portion of a lower portion of the second conductor layer 3. The recess 2a of the first conductor layer 2 is slightly larger than the protrusion 3c which is part of the second conductor layer 3 and is fitted to the protrusion 3c of the second conductor layer 3. In this state, the second conductor layer 3 is bonded onto the first conductor layer 2. The recess 2a is formed in the first conductor layer 2 by, for example, pressing or machining. The recess 2a may be formed before or after the first conductor layer 2 is bonded onto the ceramic insulating substrate 1. The protrusion 3c is formed on the second conductor layer 3 by, for example, pressing or machining.

According to the semiconductor device 100 according to the fourth embodiment as described above, the recess 2a fitted to part of the second conductor layer 3 is provided in the first conductor layer 2. According to such a configuration, the same effects as those of the third embodiment can be obtained.

Note that a shape of the recess 2a in a plan view may be a polygon such as a rectangle or a hexagon, or may be a circle. In a case where the shape of the recess 2a in plan view is a polygon, it is possible to prevent rotation of one of the first conductor layer 2 and the second conductor layer 3 with respect to the other.

### Fifth Embodiment

FIG. 5 is a cross-sectional view illustrating a configuration of the semiconductor device 100 according to a fifth embodiment. The configuration of FIG. 5 is similar to the configuration in which a recessed and relatively thin step portion 2b is provided in an outer peripheral portion of the first conductor layer 2 in the cross-sectional view in the configuration of FIG. 1. In the example of FIG. 5, the step portion 2b is provided in the outer peripheral portion of an upper surface of the first conductor layer 2 on the second conductor layer 3 side. The step portion 2b is formed in the first conductor layer 2 by, for example, pressing or machining. The step portion 2b may be formed before or after the first conductor layer 2 is bonded onto the ceramic insulating substrate 1. A depth of the step portion 2b may be, for example, half the thickness of the first conductor layer 2 or less by half cutting. A width of the step portion 2b is, for example, 50 μm or more and 5 mm or less.

The thickness of the first conductor layer 2 may be, for example, about 0.1 mm to 2 mm or may be less than 0.1 mm. However, if the thickness of the first conductor layer 2 is less than 0.1 mm, the space 4 between the overhang portion 3a and the ceramic insulating substrate 1 becomes small, so that the sealing member 10 is less likely to fill the space 4.

In contrast, according to the semiconductor device 100 of the fifth embodiment, the recessed step portion 2b is provided in the outer peripheral portion of the first conductor layer 2. According to such a configuration, a size of the space 4 between the overhang portion 3a and the ceramic insulating substrate 1 can be secured, so that it becomes easy to fill the space 4 with the sealing member 10. In addition, even in a case where the length of protrusion of the overhang portion 3a cannot be made longer in order to make the semiconductor device 100 smaller, an anchor effect can be obtained by filling the space between the second conductor layer 3 and the step portion 2b with the sealing member 10. It is therefore possible to achieve both reduction in size and improvement in reliability of the semiconductor device 100.

### Sixth Embodiment

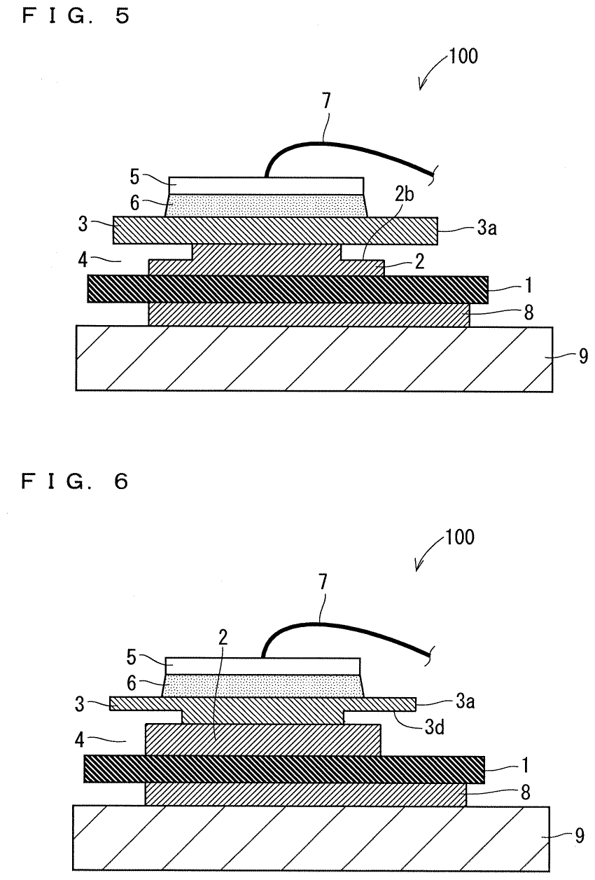

FIG. 6 is a cross-sectional view illustrating a configuration of the semiconductor device 100 according to a sixth embodiment. The configuration of FIG. 6 is similar to the configuration in which a recessed and relatively thin step portion 3d is provided in an outer peripheral portion of the second conductor layer 3 in the cross-sectional view in the configuration of FIG. 1. In the example of FIG. 6, the step portion 3d is provided in the outer peripheral portion of a lower surface of the second conductor layer 3 on the first conductor layer 2 side. The step portion 3d is formed in the second conductor layer 3 by, for example, pressing or machining. The formation, depth, and dimension of the step portion 3d are similar to, for example, the formation, depth, and dimension of the step portion 2b according to the fifth embodiment.

According to the semiconductor device 100 according to the sixth embodiment as described above, the recessed step portion 3d is provided in the outer peripheral portion of the surface of the second conductor layer 3 on the first conductor layer 2 side. According to such a configuration, effects similar to those of the fifth embodiment can be obtained.

Note that the fifth embodiment and the sixth embodiment may be combined. In other words, the step portion 2b may be provided in the first conductor layer 2, and the step portion 3d may be provided in the second conductor layer 3.

### Seventh Embodiment

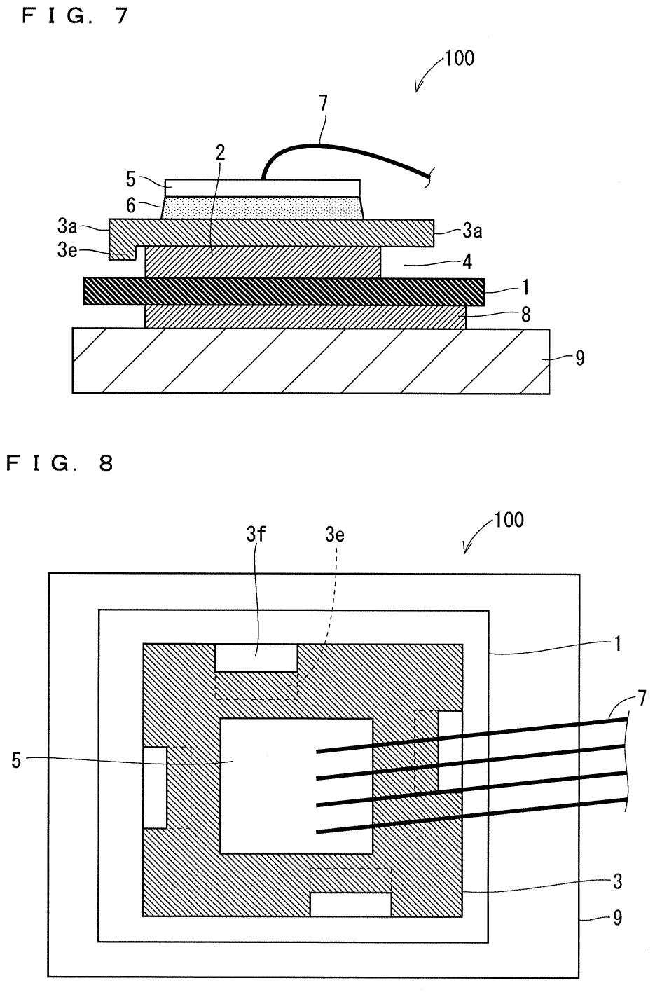

FIG. 7 is a cross-sectional view illustrating a configuration of the semiconductor device 100 according to a seventh embodiment, and FIG. 8 is a top view illustrating the configuration of the semiconductor device 100. Note that in FIG. 8, a protrusion 3e is located behind the second conductor layer 3 other than the protrusion 3e, and thus is illustrated by a dotted line which is a hidden line.

The configurations of FIGS. 7 and 8 are similar to the configuration in which the protrusion 3e protruding toward the ceramic insulating substrate 1 is provided in the overhang portion 3a, and a cutout portion 3f is provided in an outer peripheral portion of the overhang portion 3a in plan view in the configuration of FIG. 1.

For example, the protrusion 3e is formed by providing a cut at both ends of part of each side portion of the second conductor layer 3 by machining, laser cutting, or press working, and bending the part downward by, for example, pressing. As illustrated in FIG. 8, the cutout portion 3f is formed in a portion of the second conductor layer 3 used for the protrusion 3e. Note that the formation of the protrusion 3e and the cutout portion 3f is not limited to this.

A width of the cutout portion 3f in a direction along each side of the second conductor layer 3 is, for example, 1 mm to 10 mm, and a depth of the cutout portion 3f is, for example, 0.2 mm to 2 mm. An angle at which the protrusion 3e protrudes from the second conductor layer 3 other than the protrusion 3e is, for example, 45° to 135°, and a height of the protrusion 3e is less than the thickness of the first conductor layer 2.

According to the semiconductor device 100 according to the seventh embodiment as described above, the protrusion 3e protruding toward the ceramic insulating substrate 1 is provided in the overhang portion 3a. According to such a configuration, at the time of bonding the first conductor layer 2 and the second conductor layer 3, the first conductor layer 2 and the second conductor layer 3 are easily positioned, and misalignment therebetween can be reduced, so that a length of protrusion of the overhang portion 3a can be stabilized.

Further, in the seventh embodiment, the cutout portion 3f is provided in the outer peripheral portion of the overhang portion 3a in plan view. According to such a configuration, peeling of the sealing member 10 in the side direction can be prevented by an anchor effect obtained by filling the cutout portion 3f with the sealing member 10.

### Eighth Embodiment

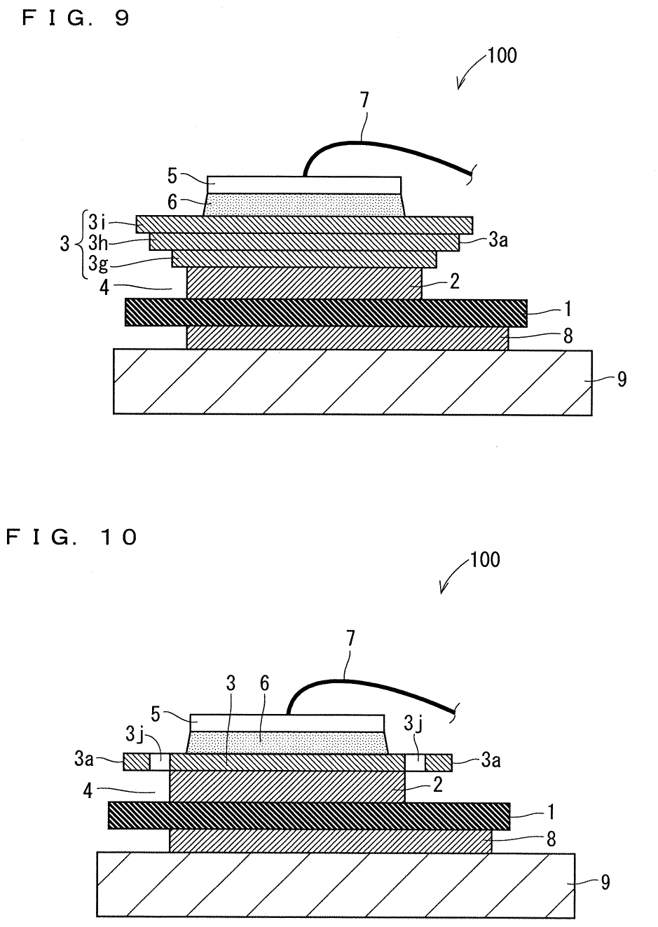

FIG. 9 is a cross-sectional view illustrating a configuration of the semiconductor device 100 according to an eighth embodiment. The configuration of FIG. 9 is similar to the configuration in which the second conductor layer 3 includes a plurality of partial layers 3g, 3h, and 3i stacked in a thickness direction (direction corresponding to the vertical direction in FIG. 9) of the second conductor layer 3 in the configuration of FIG. 1. A side end portion of a partial layer far from the first conductor layer 2 among the plurality of partial layers 3g to 3i protrudes in the side direction from a side end portion of a partial layer close to the first conductor layer 2 among the plurality of partial layers 3g to 3i. Materials or thicknesses of the plurality of partial layers 3g to 3i do not need to be the same, and may be changed as necessary. The number of the plurality of partial layers included in the second conductor layer 3 is not limited to three.

According to the semiconductor device 100 according to the eighth embodiment as described above, the first conductor layer 2 includes the plurality of partial layers 3g to 3i, and the side end portion of the partial layer far from the first conductor layer 2 protrudes in the side direction from the side end portion of the partial layer close to the first conductor layer 2. According to such a configuration, a path to the space 4 between the overhang portion 3a and the ceramic insulating substrate 1 can be widened, so that it is easy to fill the space 4 with the sealing member 10 at the time of manufacturing. In addition, for example, in a case where the size of the semiconductor element 5 varies and a bonding area has a margin, a size of the space 4 can be increased while securing a distance and insulation between the circuit patterns. In addition, for example, if the material of any one of the partial layers 3g to 3i is aluminum and the material of any one of the remaining partial layers is copper, warpage of the semiconductor device 100 can be prevented.

### Ninth Embodiment

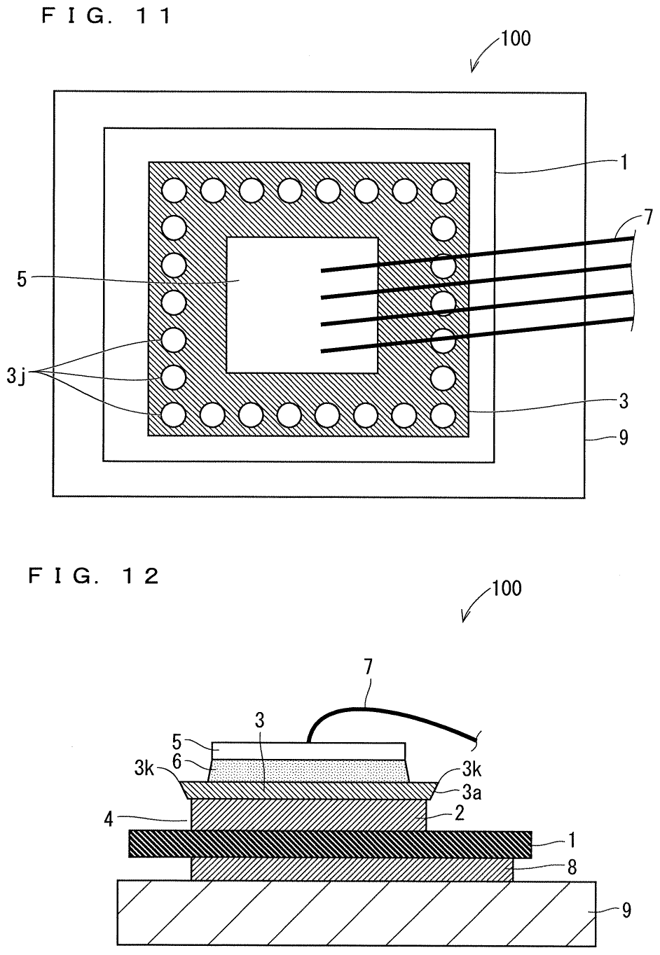

FIG. 10 is a cross-sectional view illustrating a configuration of the semiconductor device 100 according to a ninth embodiment, and FIG. 11 is a top view illustrating the configuration of the semiconductor device 100. The configurations of FIGS. 10 and 11 are similar to the configuration in which a through hole 3j is provided in the overhang portion 3a along the thickness direction of the second conductor layer 3 in the configuration of FIG. 1. A diameter of the through hole 3j is, for example, 80% or more of the thickness of the second conductor layer 3, and is formed by machining or pressing.

According to the semiconductor device 100 according to the ninth embodiment as described above, the through hole 3j is provided in the overhang portion 3a along the thickness direction of the second conductor layer 3. According to such a configuration, peeling of the sealing member 10 in the side direction can be prevented by an anchor effect obtained by filling the through hole 3j with the sealing member 10. In addition, the sealing member 10 easily flows into the space 4 under the overhang portion 3a through the through hole 3j at the time of manufacturing, so that it becomes easy to fill the space 4 with the sealing member 10.

### Tenth Embodiment

FIG. 12 is a cross-sectional view illustrating a configuration of the semiconductor device 100 according to a tenth embodiment. The configuration of FIG. 12 is similar to the configuration in which a corner portion 3k of the overhang portion 3a in the cross-sectional view has an acute angle in the configuration of FIG. 1. In the example of FIG. 12, the corner portion 3k formed by an upper surface and a side surface of the overhang portion 3a has an acute angle. The corner portion 3k is formed by, for example, machining or pressing, and an angle of an internal angle of the corner portion 3k is, for example, 45° or less.

In a case where peeling of the sealing member 10 cannot be prevented, a crack is generally generated in the sealing member 10, and there is a possibility that the life and reliability of the semiconductor device 100 degrade depending on a place where the crack is generated.

In contrast, according to the semiconductor device 100 of the tenth embodiment, the corner portion 3k of the overhang portion 3a in the cross-sectional view has an acute angle. According to such a configuration, even if a crack is generated, the acute corner portion 3k can intentionally progress the crack in a direction in which influence on the semiconductor device 100 is low. The direction in which the influence on the semiconductor device 100 is low is, for example, a direction away from the semiconductor element 5. As a result, a crack progressing direction can be controlled, so that it is possible to prevent degradation of the life and reliability of the semiconductor device 100.

Note that the embodiments and modifications can be freely combined, and the embodiments and modifications can be appropriately modified or omitted.

The above description is illustrative and not restrictive in all aspects. It is understood that numerous modifications not illustrated can be assumed.

### EXPLANATION OF REFERENCE SIGNS

1: ceramic insulating substrate
2: first conductor layer
2a: recess
2b: step portion
3: second conductor layer
3a: overhang portion
3b: recess
3c, 3e: protrusion
3d: step portion
3f: cutout portion
3g, 3h, 3i: partial layer
3j: through hole
3k: corner portion
4: space
5: semiconductor element
8: third conductor layer
10: sealing member
11: fourth conductor layer
100: semiconductor device

1. A semiconductor device comprising:
an insulating substrate;
a first conductor layer bonded onto the insulating substrate;
a second conductor layer bonded onto the first conductor layer and having an overhang portion that is a side end portion protruding in a side direction from a side end portion of the first conductor layer;
a sealing member having a portion buried in a space between the overhang portion and the insulating substrate; and
a semiconductor element covered with the sealing member.

2. The semiconductor device according to claim 1, further comprising:
a third conductor layer bonded under the insulating substrate; and
a fourth conductor layer bonded under the third conductor layer and having rigidity different from rigidity of the third conductor layer.

3. The semiconductor device according to claim 1, wherein a recess to be fitted to part of the first conductor layer is provided in the second conductor layer.

4. The semiconductor device according to claim 1, wherein a recess to be fitted to part of the second conductor layer is provided in the first conductor layer.

5. The semiconductor device according to claim 1, wherein a recessed step portion is provided in an outer peripheral portion of the first conductor layer in a cross-sectional view.

6. The semiconductor device according to claim 1, wherein a recessed step portion is provided in an outer peripheral portion of the second conductor layer in a cross-sectional view.

7. The semiconductor device according to claim 1, wherein a protrusion protruding toward the insulating substrate is provided in the overhang portion.

8. The semiconductor device according to claim 1, wherein a cutout is provided in an outer peripheral portion of the overhang portion in plan view.

9. The semiconductor device according to claim 1, wherein
the second conductor layer includes a plurality of partial layers stacked in a thickness direction of the second conductor layer, and
a side end portion of a partial layer far from the first conductor layer among the plurality of partial layers protrudes in the side direction from a side end portion of a partial layer close to the first conductor layer among the plurality of partial layers.

10. The semiconductor device according to claim 1, wherein a through hole is provided in the overhang portion along a thickness direction of the second conductor layer.

11. The semiconductor device according to claim 1, wherein a corner portion of the overhang portion in a cross-sectional view has an acute angle.

12. The semiconductor device according to claim 1, wherein a material of the semiconductor element is a wide band gap semiconductor.
